(19) United States
(12) Patent Application Publication
(10) Pub. No.: US 2013/0160811 A1
(43) Pub. Date: Jun. 27, 2013

(54) SOLAR POWER SUPPLY APPARATUS AND SOLAR BATTERY

(71) Applicants: WEI-GUO XIAO, Shenzhen City (CN); YI-YING CHEN, Tu-Cheng (TW); CHIU-HSIUNG LIN, Tu-Cheng (TW)

(72) Inventors: WEI-GUO XIAO, Shenzhen City (CN); YI-YING CHEN, Tu-Cheng (TW); CHIU-HSIUNG LIN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/459,106

(22) Filed: Apr. 28, 2012

(30) Foreign Application Priority Data
Dec. 27, 2011 (CN) 201110444463.3

(51) Int. Cl. H01L 31/05; H01L 31/0224

(52) U.S. Cl. 136/244; 136/256

(57) ABSTRACT

A solar battery includes a substrate, a solar panel arranged on the substrate, a positive electrode with a protruding positive electrode contact and a negative electrode with a protruding negative electrode contact arranged on the substrate, and a receiving recess. The receiving recess is defined between the solar panel and at least one of the positive electrode and the negative electrode. The receiving recess fittingly receives a positive electrode contact and/or a negative electrode contact of another similar solar battery, thus enabling the positive electrode contact of the another similar solar battery to be selectively and electrically connected to one of the positive electrode and the negative electrode of the another similar solar battery, and enabling or disabling the negative electrode contact of the another similar solar battery to be electrically connected to the negative electrode of the another similar solar battery.

### BACKGROUND

1. Technical Field

The present disclosure relates to solar power supply apparatus and solar batteries, and particularly, to a solar power supply apparatus and a solar battery with changeable service voltage.

2. Description of the Related Art

A solar power supply apparatus may include several solar batteries, a fixing mechanism to fix the solar batteries, an input electrode, and an output electrode. A solar panel is comprised of a certain plurality of solar batteries, in a constant number, which results in a fixed and constant service voltage. A solar power supply with different service voltages are needed for different electronic devices.

Therefore, there is room for improvement within the art.

### BRIEF DESCRIPTION OF THE DRAWINGS

The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric exploded view of a solar battery in accordance with an exemplary embodiment.

FIG. 2 is a sectional view of the solar battery of FIG. 1, in accordance with an exemplary embodiment.

FIG. 3 is a sectional view of the solar battery of FIG. 1, in accordance with another exemplary embodiment.

FIG. 4 is an assembled view of a plurality of solar batteries in FIG. 1 connected in parallel.

FIG. 5 is an assembled view of a plurality of solar batteries in FIG. 1 connected in series.

### DETAILED DESCRIPTION

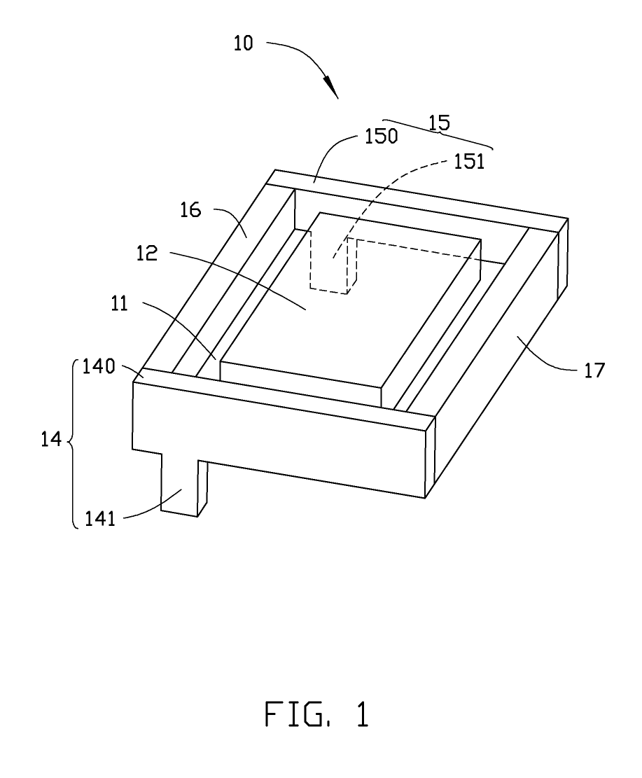

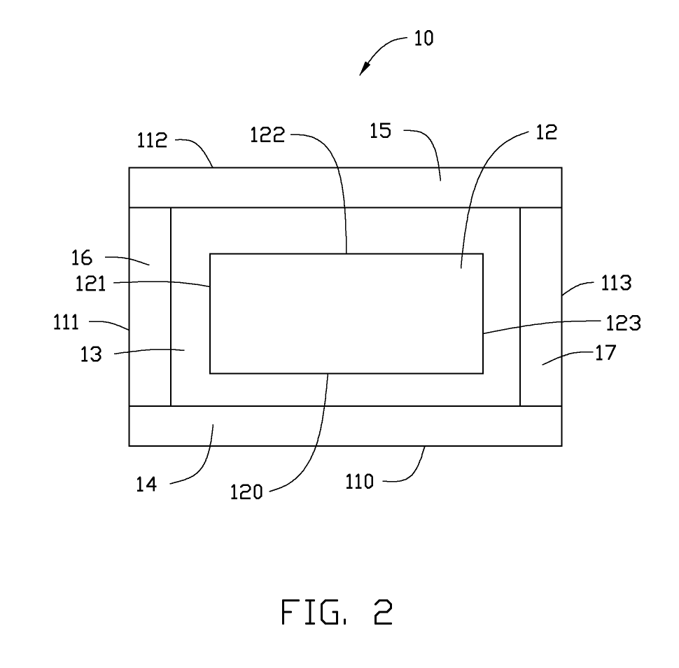

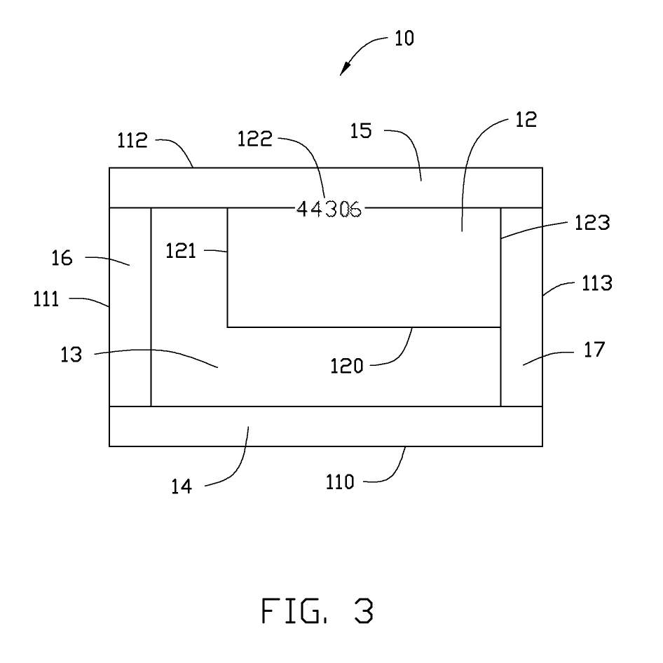

FIG. 1 illustrates a solar battery 10 employed in a solar power supply apparatus or array (not shown). The solar battery 10 includes a substrate 11, a solar panel 12, a receiving recess 13 (shown in FIGS. 2-3), a positive electrode 14, and a negative electrode 15. The solar panel 12 is arranged on the substrate 11. The positive electrode 14 and the negative electrode 15 are arranged at opposite ends of the substrate 11.

The positive electrode 14 includes a body 140 and a positive electrode contact 141 perpendicularly protruding from a lower edge of the body 140. The negative electrode 15 includes a body 150 and a negative electrode contact 151 perpendicularly protruding from a lower edge of the body 150. The receiving recess 13 can selectively and fittingly receive the positive electrode contact 141 and the negative electrode contact 151 of another similar solar battery 10 if the two solar batteries 10 are arranged together. The positive electrode contact 140 and the positive electrode contact 151 of the another similar solar battery 10 can be electrically connected to the positive electrode 14 and/or to the negative electrode 15 of the solar battery 10 if positioned accordingly.

The solar battery 10 further includes a first insulating portion 16 and a second insulating portion 17 arranged on the substrate 11 at two opposite sides of the solar panel 12 between the positive electrode 14 and the negative electrode 15.

Referring to FIG. 2, in the embodiment, the positive electrode 14 is arranged along an edge 110 of the substrate 11 and spaced from a side 120 of the solar panel 12. The negative electrode 15 is arranged along an edge 112 of the substrate 11 and spaced from a side 122 of the solar panel 12. The first insulating portion 16 is arranged along an edge 111 of the substrate 11 and spaced from a side 121 of the solar panel 12. The second insulating portion 17 is arranged along an edge 113 of the substrate 11 and is a predetermined distance from a side 123 of the solar panel 12. The positive electrode 14, the negative electrode 15, the first insulating portion 16, the second insulating portion 17, and the four edges of the second insulating portion 17 cooperatively bound a rectangular hollow or groove, namely, the receiving recess 13.

Referring to FIG. 3, in an alternative embodiment, the positive electrode 14, the negative electrode 15, the first insulating portion 16, and the second insulating portion 17 are arranged along the four edges of the solar panel 12. The solar panel 12 may be arranged with the sides 122 and 123 respectively abutting the negative electrode 15 and the second insulating portion 17. The other two sides 120 and 121 are the predetermined distance from the first insulating portion 16 and the positive electrode 14. In this case, the receiving recess 13 is an L-shaped groove defined by the sides 120 and 121 and the first insulating portion 16 and the positive electrode 14. The receiving recess 13 may be modified according to need. For example, the receiving recess 13 may be a hole.

In a further embodiment, the positive electrode 14 may be oriented parallel to the negative electrode 15, the first insulating portion 16 may be oriented parallel to the second insulating portion 17. The first insulating portion 16 and the second insulating portion 17 may be perpendicular to the positive electrode 14 and the negative electrode 15.

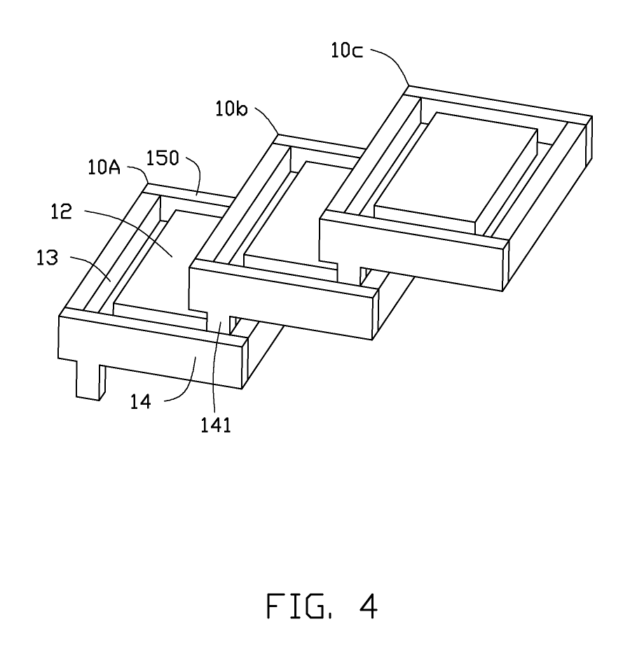

FIG. 4 shows three solar batteries 10a-10c that are slidable and electrically connected in series. The positive electrode contact 141 of a solar battery 10b is engagingly received in the receiving recess 13 of a solar battery 10a, and is electrically connected to the positive electrode 14 of the solar battery 10a. The negative electrode contact 151 of the solar battery 10b is engagingly received in the receiving recess 13 of the solar battery 10b, and is electrically connected to the negative electrode 15 of the solar battery 10a. Thus, the solar battery 10a is electrically connected to the solar battery 10b in series. The solar battery 10b is connected to the solar battery 10c also in series. Thus, the solar batteries 10a, 10b, and 10c are connected with each other in series, and the total voltage provided by the solar power supply is equal to the sum of the voltages provided by the solar batteries 10a, 10b, and 10c.

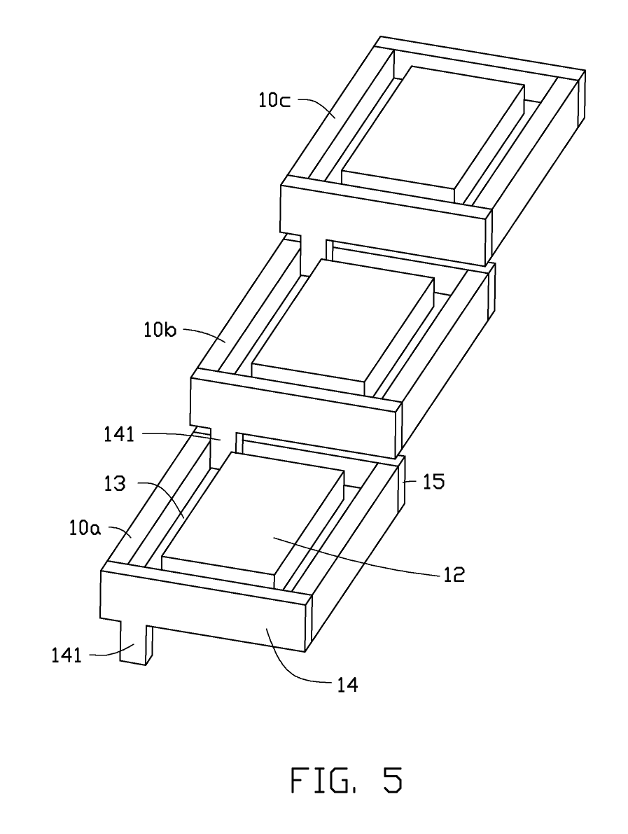

FIG. 5 shows three solar batteries 10a-10c that are slidable and electrically connected in parallel. The positive electrode contact 141 of a solar battery 10b is engagingly received in the receiving recess 13 of a solar battery 10a, and is electrically connected to the negative electrode 15 of the solar battery 10a. The negative electrode contact 151 of a solar battery 10b is out of the receiving recess 13 of the solar battery 10a. Thus, the solar battery 10a is electrically connected to the solar battery 10b in parallel. The solar battery 10b is connected to the solar battery 10c also in parallel. Thus, the solar batteries 10a, 10b, and 10c are connected with each other in parallel, and the voltage provided by the solar power supply is equal to the voltage provided by each single one of the solar battery 10a, 10b, and 10c but the output of current is higher.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A solar battery comprising:
a substrate;
a solar panel arranged on the substrate;
a positive electrode arranged on the substrate, the positive electrode comprising a body and a positive electrode contact protruding from the body away from the solar panel; and
a negative electrode arranged on the substrate, the negative electrode comprising a body and a negative electrode contact protruding from the body away from the solar panel; and
a receiving recess defined between the solar panel and at least one of the positive electrode and the negative electrode, wherein the receiving recess is configured to fittingly receive a positive electrode contact and/or a negative electrode contact of another similar solar battery, thus enabling the positive electrode contact of the another similar solar battery to be selectively and electrically connected to one of the positive electrode and the negative electrode of the another similar solar battery, and enabling or disabling the negative electrode contact of the another similar solar battery to be electrically connected to the negative electrode of the another similar solar battery.

2. The solar battery as recited in claim 1, further comprising a first insulating portion and a second insulating portion arranged on the substrate at two opposite sides of the solar panel between the positive electrode and the negative electrode.

3. The solar battery as recited in claim 2, wherein the solar panel comprises four sides including a first side, a second side, a third side, and a fourth side, the positive electrode is arranged along a first edge of the substrate and spaced from the first side, the negative electrode is arranged along a second edge of the substrate and spaced from the second side, the first insulating portion is arranged along a third edge of the substrate and spaced from the third side, the second insulating portion is arranged along a fourth edge of the substrate and spaced from the fourth side, the receiving recess is a rectangular groove bounded by the positive electrode, the negative electrode, the first insulating portion, the second insulating portion, and the four edges of the second insulating portion.

4. The solar battery as recited in claim 3, wherein the positive electrode is arranged along a first edge of the substrate and spaced from the first side, the first insulating portion is arranged along a third edge of the substrate adjoining the first edge thereof and spaced from the third side adjoining the first side, the second side and the fourth side are respectively arranged abut against the negative electrode and the second insulating portion, the receiving recess is an L-shaped groove bounded by the first side and the third side of the solar panel, the first insulating portion and the positive electrode.

5. The solar battery as recited in claim 2, wherein the positive electrode is oriented parallel to the negative electrode, the first insulating portion is oriented parallel to the second insulating portion, and the first insulating portion and the second insulating portion are perpendicular to the positive electrode and the negative electrode.

6. A solar power supply apparatus comprising:
a plurality of solar batteries stacked one on another, the solar batteries electrically connected with each other, each solar battery comprising:
a substrate;
a solar panel arranged on the substrate;
a positive electrode arranged on the substrate, the positive electrode comprising a body and positive electrode contact protruding from the body away from the solar panel;
a negative electrode arranged on the substrate, the negative electrode comprising a body and a negative electrode contact protruding from the body away from the solar panel; and
a receiving recess defined between the solar panel and at least one of the positive electrode and the negative electrode, wherein the receiving recess of a lower one of each two neighboring solar batteries is configured to engagingly receive a positive electrode contact and/or a negative electrode contact of a upper one of the two neighboring of solar batteries, thus enabling the positive electrode contact of the upper one of the two neighboring solar batteries to be selectively and electrically connected to one of the positive electrode and the negative electrode of the lower one of the two neighboring solar batteries, and enabling or disabling the negative electrode contact of the upper one of the two neighboring solar batteries to be electrically connected to the negative electrode of the lower one of the two neighboring solar batteries.

7. The solar power supply apparatus as recited in claim 6, wherein each of solar batteries is slidable with respect to a neighboring solar battery to a position where said solar battery is connected in parallel with the neighboring solar battery, the positive electrode contact of said solar battery is engagingly received in the receiving recess of the neighboring solar battery and the positive electrode contact of said solar battery is connected to the negative electrode of the neighboring solar battery, and the positive electrode contact of said solar battery is out of the receiving recess of the neighboring solar battery.

8. The solar power supply apparatus as recited in claim 6 wherein each of solar batteries is slidable with respect to a neighboring solar battery to a position where said solar battery is connected in series with the neighboring solar battery, the positive electrode contact of said solar battery is engagingly received in the receiving recess of the neighboring solar battery and the negative electrode contact of said solar battery is connected to the negative electrode of the neighboring solar battery, the positive electrode contact of said solar battery is engagingly received in the receiving recess of the neighboring solar battery and the negative electrode contact of said solar battery is connected to the negative electrode of the neighboring solar battery.

9. The solar power supply apparatus as recited in claim 6, wherein the solar battery further comprises a first insulating portion and a second insulating portion arranged on the substrate at two opposite sides of the solar panel between the positive electrode and the negative electrode.

10. The solar power supply apparatus as recited in claim 9, wherein the positive electrode is oriented parallel to the negative electrode, the first insulating portion is oriented parallel to the second insulating portion, and the first insulating portion and the second insulating portion are perpendicular to the positive electrode and the negative electrode.

11. The solar power supply apparatus as recited in claim 9, wherein the solar panel comprises four sides including a first side, a second side, a third side, and a fourth side, the positive electrode is arranged along a first edge of the substrate and spaced from the first side, the negative electrode is arranged along a second edge of the substrate and spaced from the second side, the first insulating portion is arranged along a third edge of the substrate and spaced from the third side, the second insulating portion is arranged along a fourth edge of the substrate and spaced from the fourth side, the receiving recess is a rectangular groove bounded by the positive electrode, the negative electrode, the first insulating portion, the second insulating portion, and the four edges of the second insulating portion.

12. The solar power supply apparatus as recited in claim 11, wherein the positive electrode is arranged along a first edge of the substrate and spaced from the first side, the first insulating portion is arranged along a third edge of the substrate and spaced from the third side, the first insulating portion is arranged along a third edge of the substrate adjoining the first edge thereof and spaced from the third side adjoining the first side, the second side and the fourth side are respectively arranged abut against the negative electrode and the second insulating portion, the receiving recess is an L-shaped groove bounded by the first side and the third side of the solar panel, the first insulating portion and the positive electrode.
